(19) United States
(12) Patent Application Publication
(10) Pub. No.: US 2026/0121757 A1
(43) Pub. Date: Apr. 30, 2026

(54) REDUCTION OF WAVEGUIDE CROSSTALK WITH SUB-WAVELENGTH STRUCTURES

(71) Applicant: Volantis Semiconductor, Inc., Portland, OR (US)

(72) Inventors: Tapabrata Ghosh, San Francisco, CA (US); John Sonkoly, Boise, ID (US); Horst Wagner, Goleta, CA (US)

(73) Assignee: Volantis Semiconductor, Inc., Portland, OR (US)

(21) Appl. No.: 19/260,471

(22) Filed: Jul. 5, 2025

Related U.S. Application Data
(63) Continuation-in-part of application No. 19/243,462, filed on Jun. 19, 2025.
Application No. 19/243,462 is a continuation-in-part of application No. 19/235,870, filed on Jun. 12, 2025.
Application No. 19/235,870 is a continuation-in-part of application No. 19/230,233, filed on Jun. 6, 2025.
Application No. 19/230,233 is a continuation-in-part of application No. 19/223,614, filed on May 30, 2025.
Application No. 19/223,614 is a continuation-in-part of application No. 19/222,606, filed on May 29, 2025.
Application No. 19/222,606 is a continuation-in-part of application No. 19/211,446, filed on May 19, 2025.
Application No. 19/211,446 is a continuation-in-part of application No. 19/210,116, filed on May 16, 2025.
Application No. 19/210,116 is a continuation-in-part of application No. 19/192,587, filed on Apr. 29, 2025.
Application No. 19/192,587 is a continuation-in-part of application No. 19/192,146, filed on Apr. 28, 2025.
Application No. 19/192,146 is a continuation-in-part of application No. 19/189,471, filed on Apr. 25, 2025.
Application No. 19/189,471 is a continuation-in-part of application No. 19/188,057, filed on Apr. 24, 2025.
Application No. 19/188,057 is a continuation-in-part of application No. 19/177,834, filed on Apr. 14, 2025.
Application No. 19/177,834 is a continuation-in-part of application No. 19/093,546, filed on Mar. 28, 2025.
Application No. 19/093,546 is a continuation-in-part of application No. 19/079,851, filed on Mar. 14, 2025.
Application No. 19/079,851 is a continuation-in-part of application No. 19/056,456, filed on Feb. 18, 2025.
Application No. 19/056,456 is a continuation-in-part of application No. 19/023,647, filed on Jan. 16, 2025.
Application No. 19/023,647 is a continuation-in-part of application No. 18/978,188, filed on Dec. 12, 2024.
Application No. 18/978,188 is a continuation-in-part of application No. 18/958,107, filed on Nov. 25, 2024.
Application No. 18/958,107 is a continuation-in-part of application No. 18/940,944, filed on Nov. 8, 2024.
(60) Provisional application No. 63/714,353, filed on Oct. 31, 2024.
(60) Provisional application No. 63/720,216, filed on Nov. 14, 2024.
(60) Provisional application No. 63/750,817, filed on Jan. 29, 2025.
(60) Provisional application No. 63/750,822, filed on Jan. 29, 2025.

(51) Int. Cl. H04B 10/50; G02B 6/12; G02B 6/13; G02B 6/293

(52) U.S. Cl. CPC H04B 10/504; G02B 6/12007; G02B 6/13; G02B 6/29335

(57) ABSTRACT

Waveguides are fabricated within a photonic wafer-scale interposer (PWSI). The waveguides include a first waveguide and a second waveguide. The first waveguide and the second waveguide are within a physical spacing within the PWSI which enables evanescent coupling for at least a parallel distance. A sub-wavelength barrier is inserted between the first waveguide and the second waveguide. The sub-wavelength barrier is disposed between the first waveguide and the second waveguide for at least the parallel distance. A first modulated light beam is emitted through the first waveguide by a first optical transmitter, and a second modulated light beam is emitted through the second waveguide by a second optical transmitter. The optical transmitters can comprise optical modulators. The sub-wavelength barrier reduces or eliminates the evanescent coupling between the first modulated light beam and the second modulated light beam over the parallel distance.

### RELATED APPLICATIONS

This application is a continuation-in-part of U.S. patent application “Disaggregated Memory Structures On A Directly Modulated Photonic Wafer-Scale Interposer” Ser. No. 19/243,462, filed Jun. 19, 2025.

The U.S. patent application “Disaggregated Memory Structures On A Directly Modulated Photonic Wafer-Scale Interposer” Ser. No. 19/243,462, filed Jun. 19, 2025, is also a continuation-in-part of U.S. patent application “Optical Links With Degree Of Freedom VCSEL Modulation On A Photonic Wafer-Scale Interposer”Ser. No. 19/235,870, filed Jun. 12, 2025.

The U.S. patent application “Optical Links With Degree Of Freedom VCSEL Modulation On A Photonic Wafer-Scale Interposer” Ser. No. 19/235,870, filed Jun. 12, 2025, is also a continuation-in-part of U.S. patent application “Optical Link With VCSEL Wavelength Modulation”Ser. No. 19/230,233, filed Jun. 6, 2025.

The U.S. patent application “Optical Link With VCSEL Wavelength Modulation” Ser. No. 19/230,233, filed Jun. 6, 2025, is also a continuation-in-part of U.S. patent application “Optical Link With Modulation Of VCSEL Modes”Ser. No. 19/223,614, filed May 30, 2025.

The U.S. patent application “Optical Link With Modulation Of VCSEL Modes” Ser. No. 19/223,614, filed May 30, 2025, is also a continuation-in part of U.S. patent application “Optical Link With Polarization-Switched VCSEL Modulation” Ser. No. 19/222,606, filed May 29, 2025.

The U.S. patent application “Optical Link With Polarization-Switched VCSEL Modulation” Ser. No. 19/222,606, filed May 29, 2025, is also a continuation-in-part of U.S. patent application “Hierarchical Redundancy With Parallel Optical Links” Ser. No. 19/211,446, filed May 19, 2025.

The U.S. patent application “Hierarchical Redundancy With Parallel Optical Links” Ser. No. 19/211,446, filed May 19, 2025, is also a continuation-in-part of U.S. patent application “Waveguides Based On Nanoimprint Lithography On A Photonic Wafer Scale Interposer” Ser. No. 19/210,116, filed May 16, 2025.

The U.S. patent application “Waveguides Based On Nanoimprint Lithography On A Photonic Wafer Scale Interposer” Ser. No. 19/210,116, filed May 16, 2025, is also a continuation-in-part of U.S. patent application “Photonic Wafer-Scale Interposer With Mirrors Based on Nanoimprint Lithography”Ser. No. 19/192,587, filed Apr. 29, 2025.

The U.S. patent application “Photonic Wafer-Scale Interposer With Mirrors Based on Nanoimprint Lithography” Ser. No. 19/192,587, filed Apr. 29, 2025, is also continuation-in-part of U.S. patent application “Photonic Wafer-Scale Interposer With Micro Transfer Printed VCSELS And Back Side Power Delivery” Ser. No. 19/192,146, filed Apr. 28, 2025.

The U.S. patent application “Photonic Wafer-Scale Interposer With Micro Transfer Printed VCSELS And Back Side Power Delivery” Ser. No. 19/192,146, filed Apr. 28, 2025, is also a continuation-in-part of U.S. patent application “Photonic Wafer Scale Interposer With Integrated Crystallographic Etched Mirrors And Pre-Angled Light” Ser. No. 19/189,471, filed Apr. 25, 2025.

The U.S. patent application “Photonic Wafer Scale Interposer With Integrated Crystallographic Etched Mirrors And Pre-Angled Light” Ser. No. 19/189,471, filed Apr. 25, 2025, is also a continuation-in-part of U.S. patent application “Photonic Wafer Scale Interposer With Angled Beam Grating Couplers”Ser. No. 19/188,057, filed Apr. 24, 2025.

The U.S. patent application “Photonic Wafer Scale Interposer With Angled Beam Grating Couplers” Ser. No. 19/188,057, filed Apr. 24, 2025, is also a continuation-in-part of U.S. patent application “Back Side Power Delivery For Wafer-Scale Integration With An Isometric Grid Array With Compression Pins”Ser. No. 19/177,834, filed Apr. 14, 2025.

The U.S. patent application “Back Side Power Delivery For Wafer-Scale Integration With An Isometric Grid Array With Compression Pins” Ser. No. 19/177,834, filed Apr. 14, 2025, is also a continuation-in-part of U.S. patent application “Back Side Power Delivery For Wafer-Scale Integration With Laser Assisted Bonding” Ser. No. 19/093,546, filed Mar. 28, 2025.

The U.S. patent application “Back Side Power Delivery For Wafer-Scale Integration With Laser Assisted Bonding” Ser. No. 19/093,546, filed Mar. 28, 2025, is also a continuation-in-part of U.S. patent application “Photonic Wafer-Scale Interposer With Tapered Waveguides” Ser. No. 19/079,851, filed Mar. 14, 2025.

The U.S. patent application “Photonic Wafer-Scale Interposer With Tapered Waveguides” Ser. No. 19/079,851, filed Mar. 14, 2025, is also a continuation-in-part of U.S. patent application “Back Side Power Delivery For Wafer-Scale Integration With An Isometric Grid Compression Plate” Ser. No. 19/056,456, filed Feb. 18, 2025, which claims the benefit of U.S. provisional patent applications “Chiplet-Based Optical Wafer-Scale Network Switch” Ser. No. 63/750,817, filed Jan. 29, 2025, and “Wafer-Scale Integration Power Delivery With An Isotropic Conductive Adhesive”Ser. No. 63/750,822, filed Jan. 29, 2025.

The U.S. patent application “Back Side Power Delivery For Wafer-Scale Integration With An Isometric Grid Compression Plate” Ser. No. 19/056,456, filed Feb. 18, 2025, is also a continuation-in-part of U.S. patent application “Back Side Power Delivery For Wafer-Scale Integration With Solderless Modular Power Substrates” Ser. No. 19/023,647, filed Jan. 16, 2025, which claims the benefit of U.S. provisional patent applications “Cooling For Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Back Side Power Delivery For Wafer-Scale Integration With Solderless Modular Power Substrates” Ser. No. 19/023,647, filed Jan. 16, 2025, is also a continuation-in-part of U.S. patent application “Wafer-Scale Integration With A Stiffening Isometric Grid Array” Ser. No. 18/978,188, filed Dec. 12, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Wafer-Scale Integration With A Stiffening Isometric Grid Array” Ser. No. 18/978,188, filed Dec. 12, 2024, is also a continuation-in-part of U.S. patent application “Cold Plate Cooling For Wafer-Scale Integration With Back Side Modular Power Delivery” Ser. No. 18/958,107, filed Nov. 25, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Cold Plate Cooling For Wafer-Scale Integration With Back Side Modular Power Delivery” Ser. No. 18/958,107, filed Nov. 25, 2024, is also a continuation-in-part of U.S. patent application “Back Side Wafer-Scale Integration With Modular Power Delivery” Ser. No. 18/940,944, filed Nov. 8, 2024, which claims the benefit of U.S. provisional patent application “Cooling for Wafer-Scale Integration With Back Side Power Coupling”Ser. No. 63/714,353, filed Oct. 31, 2024.

Each of the foregoing applications is hereby incorporated by reference in its entirety.

### FIELD OF ART

This application relates generally to transmitting data and more particularly to reduction of waveguide crosstalk with sub-wavelength structures.

### BACKGROUND

The theoretical prediction of electromagnetic waves by Clerk Maxwell, and the experimental work of Heinrich Hertz, propelled scientists and engineers to discover and utilize ever increasing frequencies within the electromagnetic spectrum. With generating and utilizing higher frequencies came discoveries that the higher frequencies behaved differently from the lower frequencies. Long waves (30-300 KHz), medium waves (300 KHz-3 MHz), and short waves (3-30 MHz) were known to travel over long distances, including beyond the horizon, and even around the earth. These frequency ranges or “bands” are relatively easy to generate and remain in use today. However, scientists and engineers soon discovered that the advantages of these bands had limitations including low information carrying capacity, making information transfer slow. Further, the transmissions can potentially be heard around the world, causing the bands to quickly fill to avoid frequency reuse.

As transmission technologies improved, the discovery and deployment of the high frequency (VHF) (30-300 MHz) and ultra-high frequency (UHF) (300 MHz-3 GHz) bands vastly enhanced information transfer capacity and performance. However, the signal strengths of VHF and UHF transmissions fall off quickly over distance, and the transmission distance quickly changes from over the horizon to line-of-sight. For even higher frequency bands including super high frequency (SHF) (3-30 GHz) and extremely high frequency (EHF) (30-300 GHz) bands, the increased carrying capacity comes at the cost of even faster signal decay, plus ever tighter line-of-sight tolerances.

Techniques have been developed for carrying the higher frequencies more reliably. Transmission lines and waveguides are used for handling propagation of high frequency waves. Transmission lines typically include cables or structures for transferring energy. The transmission lines can include twisted wire pairs, coaxial cables, and for higher frequencies such as microwaves, microstrip lines. The efficacy of transmission lines to transfer waves is dependent on attenuation, characteristic impedance, a propagation constant, and voltage standing wave ratio (VSWR). These parameters affect signal loss, reflections, signal change during travel, and transfer efficiency. Waveguides confine waves within a structure. The parameters describing waveguide efficiency include cutoff frequency (propagation minimum frequency), light mode patterns, and signal loss. While both transmission lines and waveguides transfer waves of different frequencies, they are not used interchangeably. Transmission lines can be applied to applications that include broad frequency ranges. Transmission lines are frequently used for applications ranging from electronics to telecommunications, power distribution, and commercial and public broadcasting. Waveguides, on the other hand, are typically reserved for frequencies including microwaves and higher. Another major difference is the construction of transmission lines versus waveguides. Transmission lines are typically cables, while waveguides look more like pipes or conduits. Waveguides are often lower loss compared to transmission lines. Waveguides, such as optical fibers, can be used in applications such as medical ones by eliminating inter-instrument interference. Further, optical fibers can be used with ionizing diagnostic radiation. Thus, both transmission lines and waveguides continue to find broad application in a wide range of areas.

### SUMMARY

The relentless demand for boosted processor performance has accelerated during the last several decades. Applications that are particularly computationally intensive, such as artificial intelligence (AI), climate modeling, genome sequencing, and so on, have been constrained by current technological capabilities of processors, systems-on-chip (SoCs), accelerators, servers, memory, power delivery, cooling technologies, and so on. Additional processing performance is widely indicated to be desperately needed. For example, today's large language model (LLM) training time can be measured in months, even while utilizing many processors and accelerators that are executing 24×7. Making further improvements will require advances in all system components. For example, communications between processors, accelerators, transformers, and so on must keep pace with the ability of these processing elements to perform calculations. Otherwise, these processing elements become “starved” for data and stall. When processing elements stall, no matter how fast they are, overall performance remains unimproved. Processing speed, memory access speed (latency), data transfer bandwidth, and power consumption are all critical to overall system performance, whether related to today's high performance systems or to the systems that will be created in the future.

Disclosed techniques enable improved transmitting of data. The transmitting data is enabled by reduction of waveguide crosstalk with sub-wavelength structures. Waveguides are fabricated within a photonic wafer-scale interposer (PWSI). The waveguides include a first waveguide and a second waveguide. The first waveguide and the second waveguide are within a physical spacing, within the PWSI, which enables evanescent coupling for at least a parallel distance. A sub-wavelength barrier is inserted between the first waveguide and the second waveguide. The sub-wavelength barrier is disposed between the first waveguide and the second waveguide for at least the parallel distance. A first modulated light beam is emitted through the first waveguide by a first optical transmitter, and a second modulated light beam is emitted through the second waveguide by a second optical transmitter. The optical transmitters can comprise optical modulators. The sub-wavelength barrier reduces the evanescent coupling between the first modulated light beam and the second modulated light beam over the parallel distance. The sub-wavelength barrier enables a reduction of waveguide crosstalk.

A method for transmitting data is disclosed comprising: fabricating a plurality of waveguides within a photonic wafer-scale interposer (PWSI), wherein the plurality of waveguides includes a first waveguide and a second waveguide, and wherein the first waveguide and the second waveguide are within a physical spacing within the PWSI which enables evanescent coupling for at least a parallel distance; inserting, between the first waveguide and the second waveguide, a sub-wavelength barrier, wherein the sub-wavelength barrier is disposed between the first waveguide and the second waveguide for at least the parallel distance; and emitting a first modulated light beam through the first waveguide by a first optical transmitter, and a second modulated light beam through the second waveguide by a second optical transmitter, wherein the sub-wavelength barrier reduces the evanescent coupling between the first modulated light beam and the second modulated light beam over the parallel distance.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for reduction of waveguide crosstalk with sub-wavelength structures.

FIG. 2 is a flow diagram for transmitting electrical data in parallel waveguides.

FIG. 3 is a diagram of a waveguide.

FIG. 4 is a diagram of evanescent coupling between waveguides.

FIG. 5 is a diagram for a sub-wavelength structure.

FIG. 6 is a diagram for nanoimprint lithography.

FIG. 7 is an apparatus for reduction of waveguide crosstalk with sub-wavelength structures.

FIG. 8 is a system diagram for reduction of waveguide crosstalk with sub-wavelength structures.

### DETAILED DESCRIPTION

Techniques for transmitting data based on reduction of waveguide crosstalk using sub-wavelength structures are disclosed. The endless demand for faster processors with expanded capabilities overwhelm the capabilities of today's processors and other system elements such as memories and data switches. To address the increasing demand, high performance systems-on-chip (SoCs) have been designed. The SoCs can include processors such as multiprocessors, cores, memories, switching elements, and so on. These SoCs can boast transistor counts in the tens of billions. Other devices that improve system-level performance include accelerators, such as artificial intelligence (AI) accelerators. These accelerators have been designed and developed to offload and accelerate computationally complex calculations. In a usage example, today's large language models can depend on many such scaled-out accelerators to perform training and inferencing. As raw processing power increases, the bandwidth and the speed of memory elements become limiting factors in system performance.

Thus, the increasing processing performance is driving the need for faster, higher bandwidth memory systems, leading to memory advancements such as HBM memories, where memory dies can be stacked on a single substrate.

A further avenue for boosting system performance has been to enable high speed communications between and among circuits. The circuits can be co-located on a circuit board, wafer, or interposer, or can be located on remotely from each other. In order for the circuits to continue processing without stalling, instructions, data, and so on must be delivered and collected within a narrow amount of time. Such data exchanges can suffer from bottlenecks resulting from interconnect that is not capable of keeping up with the circuits. Previously, simple bus architectures such as the Peripheral Component Interconnect (PCI) bus enabled sufficient bandwidth to keep processor elements from stalling. Stalling occurs when the processor elements are starved for data because the required data did not arrive in time. But as these elements grew in their ability to process more data more efficiently, additional methods of interconnect were developed. For example, high speed serial links such as PCI Express (PCIe) enabled Gigabit-per-second speeds on multiple “lanes. ” As processing power has further increased, optical communications have become a low power, high bandwidth alternative to wire-based techniques for transferring data between processing elements. For example, multimode fibers enable remarkably high bandwidth short-reach optical links which can be used between server racks, switches, storage, and so on.

To address these data transmitting issues, techniques for reduction of waveguide crosstalk with sub-wavelength structures are disclosed. A plurality of waveguides is fabricated within an interposer. The interposer includes a photonic wafer-scale interposer (PWSI). The interposer can be a directly modulated photonic wafer-scale interposer. Within the plurality of waveguides are a first waveguide and a second waveguide. The first waveguide and the second waveguide are within a physical spacing within the PWSI. The physical spacing or separation of the first and the second waveguide is sufficiently short so that evanescent coupling can occur for at least a parallel distance. A sub-wavelength barrier is inserted between the first waveguide and the second waveguide. The sub-wavelength barrier is disposed, placed, etc. between the first waveguide and the second waveguide for at least the parallel distance. The sub-wavelength barrier can extend beyond the parallel distance of the waveguides. A first modulated light beam is emitted through the first waveguide by a first optical transmitter, and a second modulated light beam is emitted through the second waveguide by a second optical transmitter. The modulated light beams can be based on degree of freedom modulation. The first optical transmitter can comprise a first optical modulator, and the second optical transmitter can comprise a second optical modulator. The first optical modulator can include a first ring resonator, and the second optical modulator can include a second ring resonator. The optical transmitters can also include VCSELs, laser diodes, and so on. The sub-wavelength barrier reduces or eliminates the evanescent coupling between the first modulated light beam and the second modulated light beam over the parallel distance. The sub-wavelength barrier reduces or eliminates crosstalk between the waveguides.

The light emitted by an optical transmitter can be modulated. The modulating the light of an optical transmitter enables transmitting data between a first circuit and a second circuit, where the first circuit and the second circuit can be bonded to the PWSI. The transmitting can be based on the first modulated light beam from the first optical transmitter. Additional data can be transmitted, transferred, and so on. Modulating light enables transferring other data, by a third circuit bonded to the PWSI, to a fourth circuit bonded to the PWSI. The transferring can be based on the second modulated light beam from the second optical transmitter. The circuits can be chiplets, SoCs, wafers, ASICs, cores, cores on wafers, and so on. The transmitting, the transferring, and so on is enabled by optical elements such as the first and the second optical transmitters. The first optical transmitter and the second optical transmitter can be based on a variety of light sources such as ring oscillators, vertical-cavity surface-emitting lasers (VCSELs), laser diodes, and so on. Modulating the light emitted by the first optical transmitter and by the second optical transmitter can be based on modulating a degree of freedom of a light source such as a VCSEL. The modulated degree of freedom of a first VCSEL can be different from the modulated degree of freedom of a second VCSEL. To address crosstalk between waveguides, reducing or eliminating evanescent coupling between the first waveguide and the second waveguide is critical to successfully transmitting data. The second circuit receives the first modulated light beam from the first VCSEL. The fourth circuit obtains the other data that was transferred. The obtaining is based on decoding the second modulated light beam. The data that is transmitted and the data that is transferred can be decoded. The decoding can include converting a modulated degree of freedom optical signal to an electrical signal.

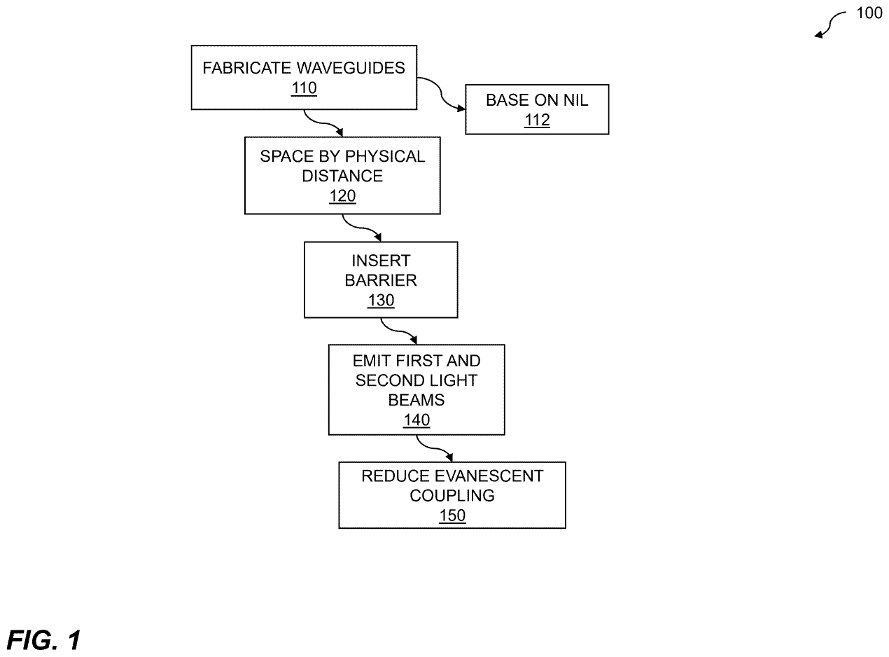

FIG. 1 is a flow diagram for reduction of waveguide crosstalk with sub-wavelength structures. The flow 100 includes fabricating 110 a plurality of waveguides within a photonic wafer-scale interposer (PWSI), wherein the plurality of waveguides includes a first waveguide and a second waveguide. In embodiments, the first waveguide and the second waveguide comprise co-propagating waveguides. A co-propagating waveguide, also called a coplanar waveguide, can comprise a waveguide and its surrounding insulator configured in a same plane. The plurality of waveguides can be fabricated using a variety of fabrication technologies. In a usage example, the plurality of waveguides is fabricated within a silicon-on-insulator technology. In embodiments, the fabricating and the inserting (described below) are based on a nanoimprint lithography (NIL) process 112. A NIL process enables creation of nanoscale patterns in a material such as resist. The resist can receive a pattern from a stamp that is compressed into the resist. The resist can be cured, where the cured resist can protect the material beneath the resist, while the uncured resist can enable processing such as etching of the material below the uncured photoresist. In embodiments, the NIL process comprises a full-wafer nanoimprint process. The use of the NIL process can enable fabrication of waveguides and other features that cannot be reliably created, if at all, using other fabrication techniques. In embodiments, the first waveguide comprises a first distance and the second waveguide comprise a second distance, wherein the first distance and the second distance are greater than an exposure, on the PWSI, of a single photomask reticle.

In the flow 100, the first waveguide and the second waveguide are within a physical spacing 120 within the PWSI which enables evanescent coupling for at least a parallel distance. Discussed in further detail below, a first wave can be emitted through a first waveguide, and a second wave can be emitted through a second waveguide. The first wave and the second wave can include an evanescent wave. For an evanescent wave, a portion of the wave is contained within a waveguide, and a portion of the wave extends beyond the waveguide. An amount of energy that can be associated with the optical wave can include a core energy portion of the optical wave within the waveguide. A waveguide can be a low containment waveguide, enabling a portion of the evanescent wave to extend beyond the core of the waveguide. If a second waveguide is spaced by a physical distance that includes close proximity, then a portion of the evanescent wave can extend beyond the core of the first waveguide and into the core of the second waveguide, resulting in evanescent coupling. After the evanescent portion of the optical wave has extended into the second waveguide for a distance, the coupled wave can continue to propagate in the second waveguide without further evanescent coupling from the first waveguide. Evanescent coupling can cause crosstalk between adjacent waveguides that include optical waves. The evanescent coupling can degrade signal integrity of optical signals traveling with the waveguides in close proximity.

The flow 100 includes inserting 130, between the first waveguide and the second waveguide, a sub-wavelength barrier, wherein the sub-wavelength barrier is disposed between the first waveguide and the second waveguide for at least the parallel distance. The sub-wavelength barrier can be formed from a variety of materials. In embodiments, the sub-wavelength barrier comprises a silicon nitride barrier. The sub-wavelength barrier can be configured to substantially reduce evanescent coupling between the first waveguide and the second waveguide for at least the parallel distance. The sub-wavelength barrier can comprise multiple sub-wavelength patterns, a two-dimensional pattern, and so on. The sub-wavelength barrier can comprise multiple strips. The sub-wavelength barrier can enable a high-confinement region within a waveguide. As will be described below, a first optical transmitter, such as a first vertical-cavity surface-emitting laser (VCSEL) can send a light beam through the first waveguide. A second optical transmitter, such as a second VCSEL, can send a light beam through the second waveguide. In embodiments, the sub-wavelength barrier comprises a width less than the wavelength of light emitted by the first VCSEL and the wavelength of light emitted by the second VCSEL. By selecting a barrier width less that the wavelength of either emitted light beam, the evanescent coupling associated with either light can be substantially reduced or eliminated.

The flow 100 includes emitting 140 a first modulated light beam through the first waveguide by a first optical transmitter, and a second modulated light beam through the second waveguide by a second optical transmitter. The first optical transmitter and the second optical transmitter can include surface-emitting light sources. In some embodiments, the first optical transmitter comprises a first optical modulator, and the second optical transmitter comprises a second optical modulator. In certain embodiments, the first optical modulator includes a first ring resonator, and the second optical modulator includes a second ring resonator. A ring resonator traps light within a closed loop when a resonance occurs. The resonance can be based on an integral multiple of a wavelength of light. The ring resonator can be used as a modulator. In embodiments, the first optical transmitter comprises a first directly modulated light source and the second optical transmitter comprises a second directly modulated light source. In addition to ring resonators, other modulated light sources can be used. In embodiments, the first directly modulated light source comprises a first vertical-cavity surface-emitting laser (VCSEL), and the second directly modulated light source comprises a second VCSEL. Other directly modulated light sources, such as laser diodes, can be used.

In embodiments, the emitting the first modulated light beam is based on modulating a degree of freedom of the first VCSEL. Various degrees of freedom can be used to modulate the first modulated light beam. The degree of freedom can include an intensity of light, a polarization of light, a light mode, a light wavelength, etc. In a usage example, the intensities of light can include a high intensity that can represent a logic one and a low intensity that can represent a logic zero. In another usage example, the light emitted by the VCSEL can include a polarization. The polarization can include an s-polarization, which includes polarization that is normal or perpendicular to a surface of incidence, or a p-polarization, which includes polarization that is parallel to a surface of incidence. The degree of freedom modulation can comprise mode modulation. A mode can include a transverse electromagnetic (TEM) mode. In a usage example, the TEM modes can include TEM₀₀, TEM₁₀, and TEM₀₁. The TEM₀₀ mode can comprise a fundamental mode, while the TEM₁₀ mode and the TEM₀₁ modes can comprise higher order modes. The degree of freedom modulation can comprise a wavelength of the first VCSEL. In a usage example, the wavelength modulation is based on a VCSEL chirp. The VCSEL chirp can be induced by the current injection.

In embodiments, a mode of light emitted by the first VCSEL is different than a mode of light emitted by the second VCSEL. The modes of light that are emitted can be chosen to complement each other, where the first mode can represent a first data stream and the second mode can represent a second data stream. In embodiments, a polarization of light emitted by the first VCSEL is different than a polarization of light emitted by the second VCSEL. In a usage example, a first polarization of light can include an s-polarization, and a second polarization of light can represent a p-polarization. In other embodiments, a wavelength of light emitted by the first VCSEL is different than a wavelength of light emitted by the second VCSEL. Note that a wavelength modulation of a VCSEL can be based on VCSEL chip. A “chirp,” which is a temporal change, can cause a change in wavelength of light emitted by a VCSEL. Different chirps can be accomplished by different amounts of current injected into the VCSEL.

In the flow 100, the sub-wavelength barrier reduces 150 the evanescent coupling between the first modulated light beam and the second modulated light beam over the parallel distance. Recall that in embodiments, the sub-wavelength barrier comprises a width less than the wavelength of light emitted by the first VCSEL and the wavelength of light emitted by the second VCSEL. By configuring the sub-wavelength barrier to reduce or eliminate a portion of the evanescent wave, crosstalk between adjacent waveguides can be reduced or eliminated. Thus, the sub-wavelength barriers can serve to highly confine the emitted light beams to their respective waveguides. The crosstalk can cause data corruption, data degradation, and the like. Disclosed embodiments can enable tight spacing of waveguides within a PWSI.

Various steps in the flow 100 may be changed in order, repeated, omitted, or the like without departing from the disclosed concepts. Various embodiments of the flow 100, or portions thereof, can be included in an apparatus for transmitting data or system that is configured to transmit data.

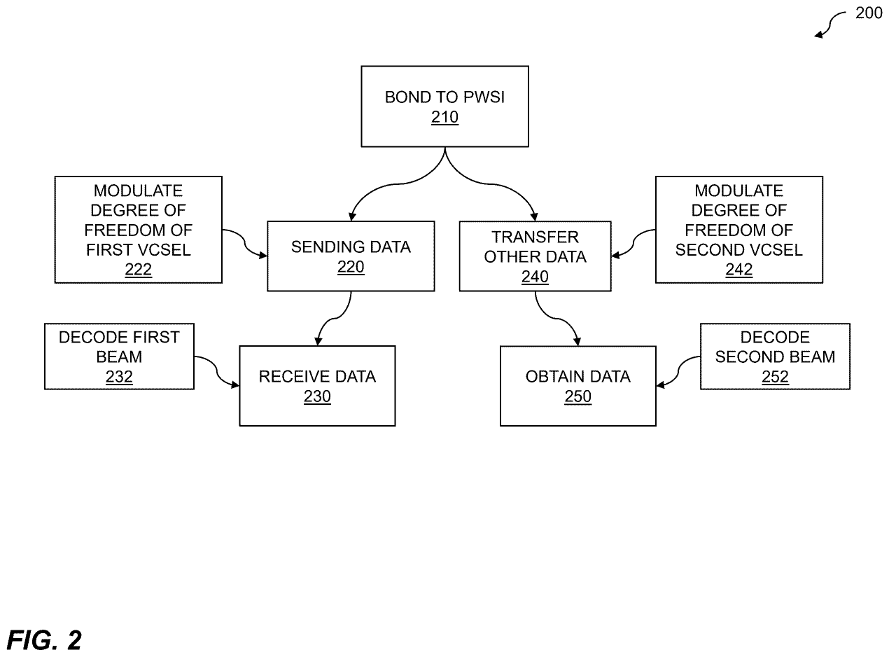

FIG. 2 is a flow diagram for transmitting electrical data in parallel waveguides.

Circuits such chips, chiplets, cores, and so on can communicate optically using waveguides, optical fibers, etc. In order to accommodate a large number of waveguides on or within a circuit board, a wafer, an interposer, and the like, the waveguides can be fabricated in close proximity. One possible result of the close proximity of the waveguides is that portions of light beams that are traveling within adjacent waveguides can “bleed over” from one waveguide to another. The phenomenon, often referred to as crosstalk, can degrade the data transmission capabilities of the light beams by confounding the beams. The crosstalk can be caused by evanescent coupling of light beams between waveguides. To counter the crosstalk challenge, structures can be placed between adjacent waveguides. Thus, the transmitting data is enabled by reduction of waveguide crosstalk with sub-wavelength structures. A plurality of waveguides is fabricated within a photonic wafer-scale interposer (PWSI), where the plurality of waveguides includes a first waveguide and a second waveguide. The first waveguide and the second waveguide are within a physical spacing within the PWSI which enables evanescent coupling for at least a parallel distance. A sub-wavelength barrier is inserted between the first waveguide and the second waveguide. The sub-wavelength barrier is disposed between the first waveguide and the second waveguide for at least the parallel distance. A first modulated light beam is emitted through the first waveguide by a first optical transmitter, and a second modulated light beam is emitted through the second waveguide by a second optical transmitter. The optical transmitters can include ring resonators, vertical-cavity surface-emitting lasers (VCSELs), laser diodes, etc. The sub-wavelength barrier reduces the evanescent coupling between the first modulated light beam and the second modulated light beam over the parallel distance. The sub-wavelength barrier can eliminate the evanescent coupling.

The flow 200 includes bonding 210 a first VCSEL and a second VCSEL to the photonic wafer-scale interposer (PWSI). The first VCSEL and the second VCSEL can include VCSELs within a plurality of VCSELs. The VCSELs can be fabricated on the PWSI, adhered to the PWSI using an adhesive or adhesive elastomeric sheets, soldered to the PWSI using solder bumps, and so on. In embodiments, the first VCSEL and the second VCSEL are bonded to the PWSI. Further, a plurality of circuits can be bonded to the PWSI. The VCSELs and the circuits can be bonded to a front side of the PWSI. The bonding the VCSELs and the bonding the circuits can include coupling the VCSELs and the circuits to interconnect associated with the PWSI. The flow 200 includes sending data 220. Recall that a modulated light beam is emitted by a surface-emitting light source such as the first VCSEL, a ring resonator, a laser diode, etc. Embodiments include sending data, by a first circuit within a plurality of circuits bonded to the PWSI, to a second circuit within the plurality of circuits bonded to the PWSI, wherein the sending is based on the first modulated light beam. The modulating the light beam can be accomplished using a variety of modulation techniques. In some embodiments, the emitting the first modulated light beam is based on modulating a degree of freedom 222 of the first VCSEL. The degree of freedom can include an intensity of light, a polarization of light, a light mode, a light wavelength, and so on. In a usage example, the light emitted by the VCSEL can include an s-polarization, which includes polarization that is normal or perpendicular to a surface of incidence, or a p-polarization, which includes polarization that is parallel to a surface of incidence. The degree of freedom modulation can comprise mode modulation. A mode can include a transverse electromagnetic (TEM) mode. In a usage example, the TEM modes can include TEM₀₀, TEM₁₀, and TEM₀₁. The TEM₀₀ mode can comprise a fundamental mode, while the TEM₁₀ mode and the TEM₀₁ mode can comprise higher order modes. The degree of freedom modulation can comprise a wavelength of the first VCSEL. In a usage example, the wavelength modulation is based on a VCSEL chirp. The VCSEL chirp can be induced by the current injection.

The flow 200 further includes receiving data 230. Some embodiments include receiving, by the second circuit, the data that was sent, wherein the receiving is based on decoding the first modulated light beam. The receiving can be accomplished by a receiver on or within the PWSI. In a usage example, the receiving includes coupling the optical information within the modulated light beam, using an optical coupler, from the first waveguide, to an optical receiver. The second optical coupler can include a grating coupler, a photo diode, a photo Darlington, etc. The optical receiver can transfer the data to the second circuit. The flow 200 includes decoding the first beam 232. The receiving is based on decoding the first modulated light beam. The decoding can be accomplished using an optical decoding element. The optical decoding element that can accomplish decoding the first modulated beam can be based on a variety of decoding techniques. In a usage example, the optical decoding element comprises a grating coupler. The grating coupler can separate different degrees of freedom of light from each other. In a usage example, the separated degrees of freedom of light can be transmitted to optical receivers, where the optical receivers can convert the optical data to electrical data. In another usage example, the grating coupler can indicate when a first degree of freedom is active in the optical medium, which can comprise a logic “1.” The absence of the signal from the grating coupler can comprise a logic “0.” Clocking, such as clock and data recovery (CDR) circuits, can synchronize the modulated light beam with the receiving and/or decoding circuits. The optical decoding element can comprise a polarization filter. The polarization filter can enable a first polarization of light to pass through the polarization filter while a second polarization of light is reflected by the polarization filter. In further embodiments, the optical decoding element comprises a polarization multiplexor (PMUX). The polarization multiplexer can separate the different polarizations of the modulated light beam at the far end of the waveguide.

The flow 200 further includes transferring other data 240. Embodiments include transferring other data, by a third circuit within the plurality of circuits bonded to the PWSI, to a fourth circuit within the plurality of circuits bonded to the PWSI, wherein the transferring is based on the second modulated light beam. The second modulated light beam is emitted by a second surface-emitting light source such as the second VCSEL, a ring resonator, a laser diode, and so on. The second modulated light beam emitted by the second surface-emitting light source can include a modulation type substantially similar to the first modulated light beam or substantially different from the first modulated light beam. The modulating the second light beam can be accomplished using a variety of modulation techniques. In some embodiments, the emitting the second modulated light beam is based on modulating a degree of freedom 242 of the second VCSEL. The degree of freedom can include an intensity of light, a polarization of light, a light mode, a light wavelength, and so on.

The flow 200 further includes obtaining data 250. Some embodiments include obtaining, by the fourth circuit, the other data that was transferred, wherein the obtaining is based on decoding the second modulated light beam. The obtaining can be accomplished by a second receiver on or within the PWSI. In a usage example, the obtaining includes coupling the optical information within the second modulated light beam, using a second optical coupler, from the second waveguide, to a second optical receiver. The second optical coupler can include a grating coupler, a photo diode, a photo Darlington, etc. The optical receiver can transfer the data to the second circuit. The flow 200 includes decoding the second beam 252. The decoding can be accomplished using a second optical decoding element. The second optical decoding element that can accomplish decoding the second modulated beam can be based on a variety of decoding techniques. In a usage example, the optical decoding element comprises a grating coupler. The grating coupler can separate different degrees of freedom of light from each other. In a usage example, the separated degrees of freedom of light can be transmitted to optical receivers, where the optical receivers can convert the optical data to electrical data. In another usage example, the grating coupler can indicate when a first degree of freedom is active in the optical medium, which can comprise a logic “1.” The absence of the signal from the grating coupler can comprise a logic “0.” Clocking, such as clock and data recovery (CDR) circuits can synchronize the second modulated light beam with the receiving and/or decoding circuits. The optical decoding element can comprise a polarization filter.

Various steps in the flow 200 may be changed in order, repeated, omitted, or the like without departing from the disclosed concepts. Various embodiments of the flow 200, or portions thereof, can be included in an apparatus for transmitting data or system that is configured to transmit data.

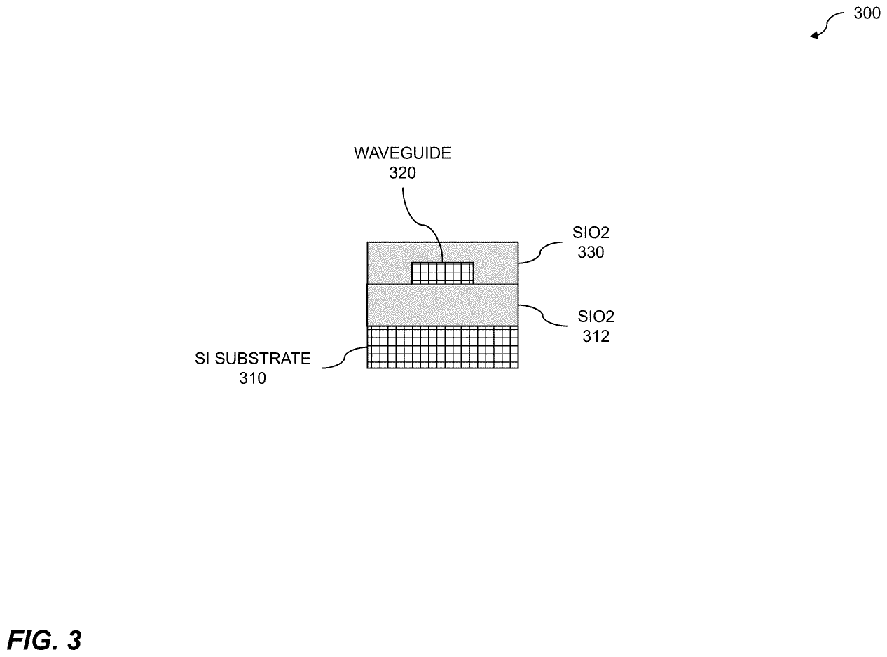

FIG. 3 is a diagram of a waveguide. A cross-section of a waveguide is shown. The waveguide can include a waveguide within a plurality of waveguides within an interposer. The waveguide can be fabricated in a technology such as a silicon-on-insulator (SOI) technology. A waveguide can be used to transfer a signal such as an optical signal between two elements. The optical signal can include a modulated light beam. The elements can include circuits, chiplets, cores, and so on. The elements can include special purpose circuits such AI accelerators, switching chiplets, and the like. The switching chiplets can be associated with a switch such as an optical wafer-scale network switch. The waveguide can be fabricated within a monolithic wafer which includes one or more circuits, chiplets, functional chips, etc. The waveguide can be fabricated within a photonic wafer-scale interposer (PWSI), where the PWSI can be based on a wafer such as a silicon wafer, a glass wafer, and so on. The wafer can be used as a substrate for the PWSI. A plurality of waveguides can be fabricated within the PWSI in order to enable high speed, high bandwidth communications between circuits. The communication between circuits can include circuits separated by a long distance on the PWSI. The waveguides can be tapered. Structures can be placed between adjacent waveguides to reduce or eliminate crosstalk between adjacent waveguides. The plurality of waveguides enable transmitting data.

The figure includes a cross-section of an example waveguide. The example waveguide can be fabricated in a silicon-on-insulator (SOI) technology as shown 300, or in another fabrication technology. A silicon substrate 310 is used. The silicon substrate can include a silicon wafer, where the silicon wafer can include a 200 mm silicon wafer, a 300 mm silicon wafer, and so on. A silicon dioxide (insulator) layer 312 can be grown, deposited, or otherwise formed on the silicon wafer. One or more waveguides, such as waveguide 320, can be formed on the insulator layer 312. Any number of waveguides can be formed on the insulator layer 312. Another insulator layer 330 can be placed over the one or more waveguides. The further insulator layer 330 can be planarized in order to enable fabrication of further elements.

The waveguide can conduct light in order to establish optical communications between an optical source and an optical receiver within the PWSI. The waveguide can be utilized by a first circuit such as a processor, an AI chiplet, a switching chiplet, etc. The first circuit can transmit data to a first surface-emitting light source. The light source can include a ring resonator, a vertical-cavity surface-emitting laser (VCSEL), a laser diode, and so on. The VCSEL can convert the data transmitted from the first circuit into optical data. The optical data can be coupled to a waveguide using an optical coupler such as a grating coupler or a mirror fabricated using a nanoimprint lithography (NIL) technique. A second optical coupler can couple light transmitted through the waveguide and can transfer the optical data to a second circuit.

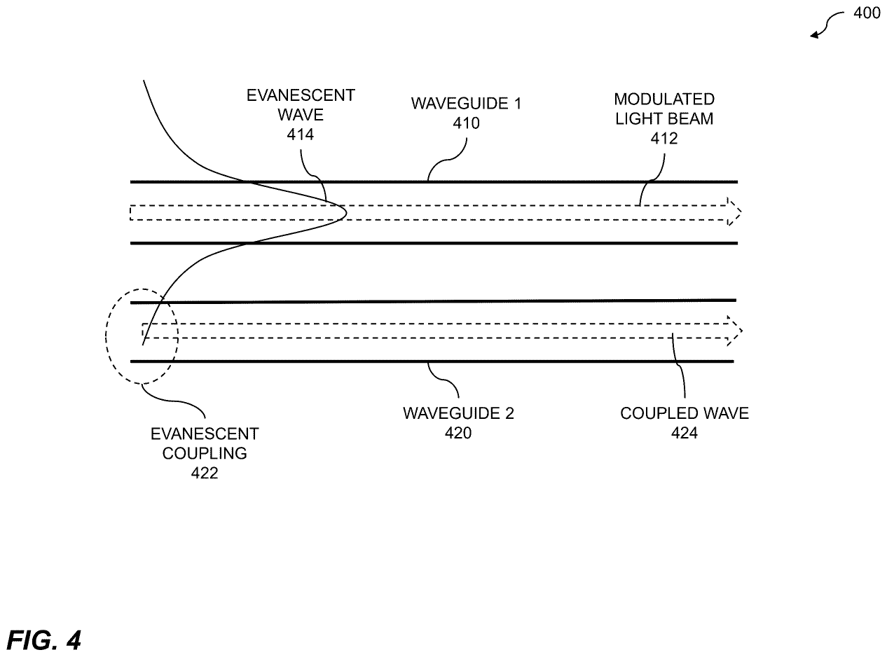

FIG. 4 is a diagram of evanescent coupling between waveguides. Data can be transmitted between circuits, chiplets, cores, etc. bonded to a photonic wafer-scale interposer (PWSI) using a waveguide. The data, which can include digital data, can be serialized and converted from digital data to optical data. The conversion of the digital data to the optical data can be accomplished using a surface-emitting light source such as a ring resonator, a vertical-cavity surface-emitting laser (VCSEL), a laser diode, a light emitting diode (LED), and so on.

The optical data can be transmitted between a first circuit and a second circuit using a waveguide within the PWSI. The optical data can be coupled to the waveguide using an optical coupler. The optical coupler can include a grating coupler, an off-axis diffractive lens, a mirror, a bent waveguide, and the like. The data that is transmitted can be received by the second circuit. In embodiments, the receiving includes coupling the optical information, by a second optical coupler, from the first waveguide, to an optical receiver. The second optical coupler can include a grating coupler, a photo diode, a photo Darlington, etc. The optical receiver can transfer the data to the second circuit. A transition can be made between at least one low confinement region and at least one high confinement region. The transition includes the first waveguide. Thus, the optical signal within the low confinement region of the waveguide must be efficiently transferred to the high confinement region. The transitioning can include a second waveguide in the plurality of waveguides, where the transitioning can be based on evanescent coupling. The evanescent coupling causes crosstalk between waveguides. The amount or degree of coupling can be reduced or eliminated. Transmitting data is enabled by reduction of waveguide crosstalk with sub-wavelength structures.

The FIG. 400 shows an example of evanescent coupling of an optical signal between a first waveguide and a second waveguide. The first waveguide and the second waveguide can include different cross-sections, low confinement regions, high confinement regions, tapering sections (which can include adiabatic tapering sections), and so on. A first waveguide is shown 410. A wave such as modulated optical light beam 412 can travel along the first waveguide. The modulated optical wave can be based on a variety of modulation techniques. In a usage example, the modulated optical wave is based on modulating a degree of freedom of a light source such as a ring resonator, a VCSEL, etc. The wave can comprise an evanescent wave 414, where a portion of the wave is contained within the waveguide and a portion of the wave extends beyond the waveguide. An amount of energy can be associated with the optical wave. The energy associated with the optical wave can include a core energy portion of the optical wave within the waveguide. A portion of the evanescent wave can extend beyond the core of the waveguide. If a second waveguide, such as waveguide 420, is placed in close proximity to the first waveguide 410, then a portion of the evanescent wave can extend beyond the core of the first waveguide and into the core of the second waveguide, accomplishing evanescent coupling 422. After the evanescent portion of the optical wave has extended into the second waveguide for a distance, the coupled wave 424 continues to propagate in the second waveguide without further evanescent coupling from the first waveguide.

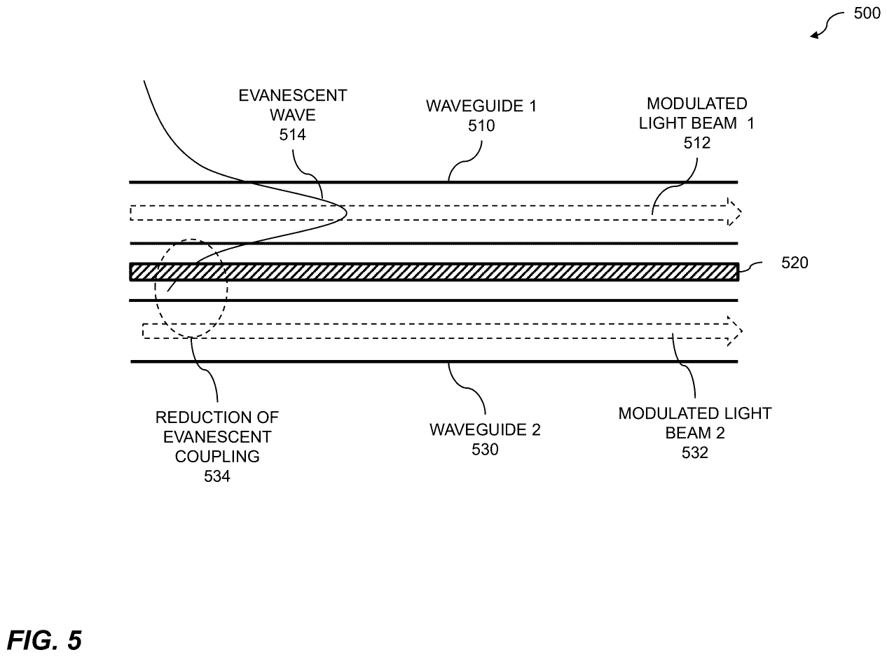

FIG. 5 is a diagram for a sub-wavelength structure. Described previously and throughout, one or more waveguides can be used for transmitting data between circuits, chiplets, cores, etc. bonded to a wafer, an interposer, a photonic wafer-scale interposer (PWSI), and so on. The data, which can include serialized data, can be converted from digital data to optical data using a surface-emitting light source such as a ring resonator, a vertical-cavity surface-emitting laser (VCSEL), a laser diode, and the like. The optical data can be transmitted between a first circuit and a second circuit by coupling the optical data to a waveguide within the PWSI.

Discussed above, when waveguides are positioned in proximity to each other, evanescent coupling can cause a portion of a wave such as a modulated light beam traveling in a first waveguide to couple in part to a modulated light beam traveling in a second waveguide. The coupling causes crosstalk between the waveguides. The crosstalk between waveguides can be reduced or substantially eliminated by inserting a barrier between the waveguides. In embodiments, the barrier comprises a sub-wavelength barrier. A sub-wavelength barrier enables transmitting data by a reduction of waveguide crosstalk.

The FIG. 500 shows a sub-wavelength structure for reduction or elimination of evanescent coupling. The evanescent coupling of an optical signal can otherwise occur between a first waveguide and a second waveguide without the sub-wavelength structure inserted between the waveguides. Noted above, the first waveguide and the second waveguide can include different cross-sections. A first waveguide, waveguide 1, is shown 510. A wave such as modulated light beam 1 512 can propagate along the first waveguide. The wave can comprise an evanescent wave 514, where a portion of the wave is contained within the waveguide and a portion of the wave extends beyond the waveguide. The optical wave can include an amount of energy. The energy associated with the optical wave can include a core energy portion. The core energy portion of the optical wave is associated with the portion of the optical wave within the waveguide. Since the first waveguide can be a low containment waveguide, a portion of the evanescent wave can extend beyond the core of the waveguide. A barrier 520 is inserted between the first waveguide and a second waveguide 530 (discussed below). Recall that two waveguides can run in parallel for a parallel distance. In embodiments, the sub-wavelength barrier is disposed between the first waveguide and the second waveguide for at least the parallel distance. The sub-wavelength barrier can affect the degree to which the evanescent wave associated with the first waveguide can be coupled to the second waveguide. The sub-wavelength barrier can attenuate, block, eliminate, and so on the evanescent coupling between the modulated light beams within the optical waveguides.

In the FIG. 500, the second waveguide, waveguide 2 530, is placed in close proximity to the first waveguide 510. The second modulated light beam, modulated light beam 2 532, can travel along the second waveguide. In the absence of the sub-wavelength barrier, a portion of the evanescent wave associated with modulated light beam 1 could extend beyond the core of waveguide 1 and into the core of the second waveguide, resulting in evanescent coupling. The sub-wavelength barrier reduces or eliminates the tail of the evanescent wave that would otherwise couple to the second waveguide, resulting in a reduction or elimination of evanescent coupling 534. In embodiments, the sub-wavelength barrier reduces the evanescent coupling between the first modulated light beam and the second modulated light beam the parallel distance.

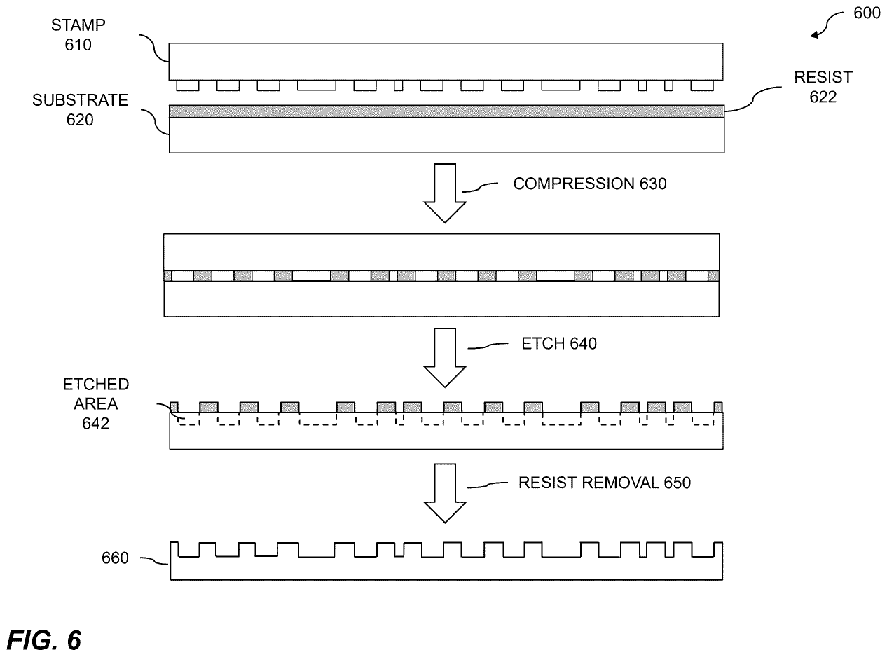

FIG. 6 is a diagram for nanoimprint lithography. Nanoimprint lithography is a technique that can be used for building a plurality of waveguides, mirrors, and other structures within a wafer, interposer, and so on. The interposer can include a photonic wafer-scale interposer (PWSI). The waveguides that are built within the PWSI are used to transmit data as modulated light beams between circuits, and the mirrors, when present, can be used to couple to the waveguides light emitted by a plurality of surface-emitting light sources. The surface-emitting light sources can include ring resonators, vertical-cavity surface-emitting lasers (VCSELs), laser diodes, and the like. The transmitting is enhanced by a reduction of waveguide crosstalk with sub-wavelength structures. The transmitting light data enables transmitting data between circuits within a plurality of circuits bonded to a front side of the PWSI.

A plurality of waveguides is fabricated within a photonic wafer-scale interposer (PWSI). The plurality of waveguides includes a first waveguide and a second waveguide. The first waveguide and the second waveguide are within a physical spacing within the PWSI which enables evanescent coupling for at least a parallel distance. A sub-wavelength barrier is inserted between the first waveguide and the second waveguide. The sub-wavelength barrier is disposed between the first waveguide and the second waveguide for at least the parallel distance. A first modulated light beam is emitted through the first waveguide by a first optical transmitter, and a second modulated light beam is emitted through the second waveguide by a second optical transmitter. The sub-wavelength barrier reduces the evanescent coupling between the first modulated light beam and the second modulated light beam over the parallel distance. In a usage example, the sub-wavelength barrier eliminates the evanescent coupling between the first modulated light beam and the second modulated light beam over the parallel distance.

The FIG. 600 shows an example of a process for nanoimprint lithography (NIL). Waveguides and sub-wavelength barriers can be fabricated within a PWSI. In embodiments, the fabricating and the inserting is based on a nanoimprint lithography (NIL) process.

The NIL can include a stamp 610 for building waveguides, sub-wavelength barriers, mirrors, and so on within the PWSI. In a usage example, the fabricating waveguides and the inserting sub-wavelength barriers includes creating a stamp. The stamp includes a plurality of topological patterns, where the plurality of topological patterns corresponds to the plurality of waveguides and sub-wavelength barriers. The stamp can be based hard materials such as silicon, silicon dioxide, nickel, or other hard materials. The stamp can be based on soft materials such as polydimethylsiloxane (PDMS) or other soft polymers that can be cured using ultraviolet (UV) light. The waveguide fabricating and the sub-wavelength inserting includes a substrate 620, which can be a PWSI, onto which a photoresist 622 is deposited. The resist can include a polymer. The stamp is used to create an impression in the photoresist on the substrate. In embodiments, the NIL process comprises a full-wafer nanoimprint process. In a usage example, the impression in the photoresist is accomplished by compressing 630, by the stamp, photoresist deposited on the PWSI. The compressing results in an imprint of the plurality of topological patterns in the photoresist. The topological patterns in the photoresist can be used to indicate where the plurality of waveguides and sub-wavelength barriers can be formed within the PWSI. The photoresist can be cured following the compression. The stamp can be removed. In a usage example, the compressing includes heating the photoresist. The heating the photoresist can harden or cure portions of the photoresist while leaving other portions of the photoresist uncured. The uncured photoresist can be removed from the substrate.

The fabricating the waveguides and the inserting the sub-wavelength barriers can include using the cured photoresist as bases for the waveguides and the barriers. The diagram 600 includes etching 640 the PWSI. The etching can be based on a “wet” etch such as a liquid etch, a “dry” etch such as a plasma etch, and so on. A dry etch can include using a plasma of reactive gases that can remove unprotected material (e.g., material not covered by the photoresist) from the substrate. In the figure, an example etched area 642 is shown. Following the etching, the remaining, cured photoresist can be removed 650 from the substrate. The result of removing the photoresist from the substrate reveals shapes 660 in the substrate. The revealed shapes in the substrate can include the waveguides and the sub-wavelength barriers. The NIL steps can be repeated. Various shapes can be made into a nanoimprinted mirror.

Note that the wavelengths within the PWSI can include wavelengths of various lengths. In embodiments, the first waveguide comprises a first distance and the second waveguide comprises a second distance, wherein the first distance and the second distance are greater than an exposure, on the PWSI, of a single photomask reticle. Thus, additional technologies beyond normal lithography can be used, such as NIL as discussed above, to fabricate the waveguides. In embodiments, the NIL process comprises a full-wafer nanoimprint process. Other technologies can be used to fabricate the waveguides. In a usage example, one or more waveguides within the PWSI are fabricated via reticle stitching.

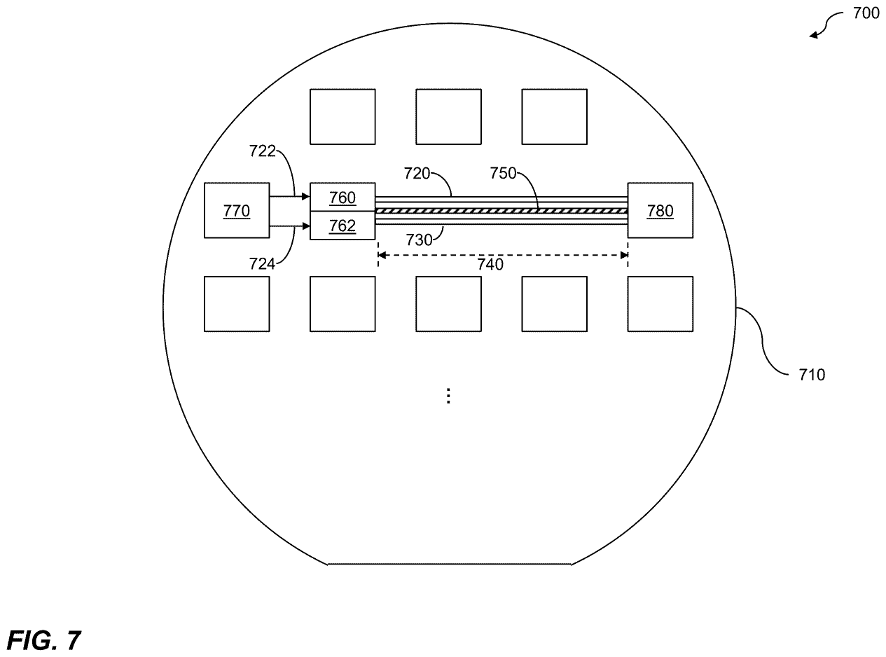

FIG. 7 is an apparatus for reduction of waveguide crosstalk with sub-wavelength structures. The sub-wavelength structures enhance transmitting modulated light beams through waveguides by reducing or eliminating crosstalk between waveguides. Circuits, which can include chips, chiplets, cores, and so on, are bonded to a photonic wafer-scale interposer (PWSI). The circuits can include AI accelerators, switching circuits, etc. The circuits can be co-located on a circuit board, wafer, or interposer such as a photonic wafer-scale interposer (PWSI); located in different multiprocessors; located in different data centers; and so on. The circuits can communicate via waveguides within a PWSI. Sub-wavelength structures can enable reduction of crosstalk between waveguides.

Data is transmitted between a first circuit and a second circuit. The transmitting is based on the first modulated light beam. Electrical data is provided by the first circuit to a first optical transmitter. The first optical transmitter converts the electrical data to optical (e.g., light) data, where the optical data is transmitted as a first modulated light beam emitted by a first optical transmitter. The modulated light beam can be based on various modulation schemes. A second modulated light beam can be emitted by a second optical source, based on transferred data provided by a third circuit.

An apparatus is disclosed for transmitting data comprising: a photonic wafer-scale interposer (PWSI); a plurality of waveguides, wherein the plurality of waveguides is fabricated within the PWSI, wherein the plurality of waveguides includes a first waveguide and a second waveguide, and wherein the first waveguide and the second waveguide are within a physical spacing, within the PWSI, which enables evanescent coupling for at least a parallel distance; a sub-wavelength barrier, wherein the sub-wavelength barrier is disposed between the first waveguide and the second waveguide for at least the parallel distance; a first optical transmitter, wherein the first optical transmitter is bonded to the PWSI and wherein the first optical transmitter emits a first modulated light beam through the first waveguide; and a second optical transmitter, wherein the second optical transmitter is bonded to the PWSI and wherein the second optical transmitter emits a second modulated light beam through the second waveguide, wherein the sub-wavelength barrier reduces the evanescent coupling between the first modulated light beam and the second modulated light beam over the parallel distance.

The apparatus 700 includes a photonic wafer-scale interposer (PWSI) 710. The PWSI can be based on a variety of materials. The PWSI can include a silicon (Si) wafer, a glass wafer, and so on. The apparatus 700 includes a plurality of waveguides, wherein the plurality of waveguides is fabricated within the PWSI, wherein the plurality of waveguides includes a first waveguide and a second waveguide, and wherein the first waveguide and the second waveguide are within a physical spacing, within the PWSI, which enables evanescent coupling for at least a parallel distance. The apparatus 700 shows a first waveguide 72, and a second waveguide 730. Although two waveguides are shown, as described above, any number of waveguides can be fabricated within the PWSI. The waveguides can be fabricated on the PWSI, within the PWSI, and so on. Discussed previously, the plurality of waveguides can be fabricated using a silicon-on-insulator (SOI) fabrication technique. Note that the fabrication process can be based on using a reticle. A pattern can be exposed onto the PWSI. The distances associated with waveguides within the plurality of waveguides can vary significantly. In embodiments, the first waveguide comprises a first distance and the second waveguide comprises a second distance, wherein the first distance and the second distance are greater than an exposure, on the PWSI, of a single photomask reticle. Other processes can also be used. In embodiments, the fabricating and the inserting (discussed below) are based on a nanoimprint lithography (NIL) process.

The waveguides can be within a close physical spacing for a parallel distance 740. The close spacing enables evanescent coupling between the two waveguides. The evanescent coupling that can be enabled between the first waveguide and the second waveguide can cause crosstalk which can cause degradation and corruption of a modulated light beam. The apparatus 700 includes a sub-wavelength barrier 750, wherein the sub-wavelength barrier is disposed between the first waveguide and the second waveguide for at least the parallel distance. The sub-wavelength barrier can reduce or eliminate evanescent coupling between the first modulated light beam and the second modulated light beam over the parallel distance. While two waveguides and one barrier are described, the PWSI can include tens, hundreds, thousands, or more waveguides. In embodiments, the PWSI includes one or more additional waveguides and one or more additional sub-wavelength barriers. The sub-wavelength barriers can be configured to reduce or eliminate the evanescent coupling based on a wavelength. In embodiments, the sub-wavelength barrier comprises a width less than the wavelength of light emitted by the first VCSEL and the wavelength of light emitted by the second VCSEL.

The apparatus 700 includes a first optical transmitter 760, wherein the first optical transmitter is bonded to the PWSI and wherein the first optical transmitter emits a first modulated light beam through the first waveguide. The first optical transmitter can comprise a ring resonator, VCSEL, laser diode, or another optical transmitter. The apparatus 700 includes a second optical transmitter 762, wherein the second optical transmitter is bonded to the PWSI and wherein the second optical transmitter emits a second modulated light beam through the second waveguide, wherein the sub-wavelength barrier reduces the evanescent coupling between the first modulated light beam and the second modulated light beam over the parallel distance. The sub-wavelength barrier can eliminate the evanescent coupling between the first modulated light beam and the second modulated light beam, as discussed above. The first optical transmitter and the second optical transmitter can be substantially the same or different types of transmitters. The first and second optical transmitter can be included on the same chip, on different chips, and so on. The first optical transmitter and the second optical transmitter can comprise various surface-emitting light sources. In some embodiments, the first optical transmitter comprises a first optical modulator, and the second optical transmitter comprises a second optical modulator. In certain embodiments, the first optical modulator includes a first ring resonator, and the second optical modulator includes a second ring resonator. In a usage example, the first ring oscillator and the second ring oscillator are bonded to a front side of the PWSI. In other embodiments, the first optical transmitter comprises a first vertical-cavity surface-emitting laser (VCSEL), and the second optical transmitter comprises a second VCSEL. The first VCSEL and the second VCSEL can be located on the same chip, array, etc., or on different chips, arrays, etc. The first VCSEL and the second VCSEL can comprise directly modulated light sources. The first VCSEL and/or the second VCSEL can comprise multimodal VCSELs.

A first circuit can send data 722 to a second circuit via the first VCSEL. Some embodiments include sending data, by a first circuit 770 within a plurality of circuits bonded to the PWSI, to a second circuit 780 within the plurality of circuits bonded to the PWSI, wherein the sending is based on the first modulated light beam. In embodiments, the emitting the first modulated light beam is based on modulating a degree of freedom of the first VCSEL. The degree of freedom can include a beam with a plurality of intensities, phases, modes, wavelengths, and so on. The DFMB emitted by the first VCSEL can be conveyed to an optical coupler. The optical coupler can couple optically the DFMB to the first waveguide. The coupling optically can be based on a grating coupler, a bent waveguide, an off-axis diffractive lens, a mirror (such as a nano-imprint lithography mirror), or another coupling method. The DFMB that was emitted by the VCSEL can be angled, where the angling can be based on a micro-optical element (MOE). The angling the DFMB can be used to complement an angle associated with the coupling the DFMB to the optical medium. The MOE can comprise a micro lens, a diffractive optical element, a Fresnel lens, an asymmetric non-focusing optical device, or another micro-optical element.

Some embodiments include receiving, by the second circuit, the data that was sent, wherein the receiving is based on decoding the first modulated light beam. The decoding can be based on a decoding element (ODE). The ODE can separate different degrees of freedom of light from the DFMB. The separated degrees of freedom of light (e.g., optical data) can be decoded into electrical data that was transmitted by the first circuit. The ODE can accomplish decoding based on a plurality of decoding techniques such as a grating coupler, a polarization filter, a polarization multiplexor (PMUX), or another element. The electrical data that was decoded can be transmitted to the second circuit. The electrical data can comprise data, control signals, and so on. The first circuit and the second circuit can be located on the PWSI, a different or a common circuit board, a different or a common wafer, a different or a common rack, and so on. The first circuit and the second circuit can be remotely located with respect to each other. “Remotely located” can include locating the first circuit and the second circuit in separate circuit boards or wafers, separate multiprocessors, separate data racks, separate data centers, and so on.

The same techniques as described above can be used to send data from a third circuit 724 to a fourth circuit via a second waveguide within the PWSI. The sub-wavelength barrier can ensure that evanescent coupling does not affect the transmissions of light within the first and second waveguide, even though they can be spaced very close to each other.

Embodiments include transferring other data, by a third circuit within the plurality of circuits bonded to the PWSI, to a fourth circuit within the plurality of circuits bonded to the PWSI, wherein the transferring is based on the second modulated light beam. In some embodiments, the emitting the second modulated light beam is based on modulating a degree of freedom of the second VCSEL. Some embodiments include obtaining, by the fourth circuit, the other data that was transferred, wherein the obtaining is based on decoding the second modulated light beam. As shown in apparatus 700, the first circuit and the third circuit can comprise the same circuit on the PWSI, which can be a chiplet, core, etc. Likewise, the second circuit and the fourth circuit can comprise the same circuit on the PWSI. Mentioned previously, the circuits can include AI accelerator chiplets, switching chiplets, ASICs, input/output (I/O) chiplets, and so on. The circuits can be connected, attached, bonded, or otherwise coupled to a circuit board, a wafer, an interposer, and so on. In a usage example, the PWSI can comprise an optical wafer-scale AI accelerator, where one or more chiplets within the plurality of chiplets comprise one or more artificial intelligence (AI) accelerators. The AI accelerator can be used for machine learning (ML), natural language processing (NLP), and the like. In another usage example, the PWSI comprises an optical wafer-scale network switch, where one or more chiplets within the plurality of chiplets comprise one or more switching chiplets. The network switch can be used to provide data to compute-intensive applications such as artificial intelligence (AI), machine learning (ML), image processing, etc.

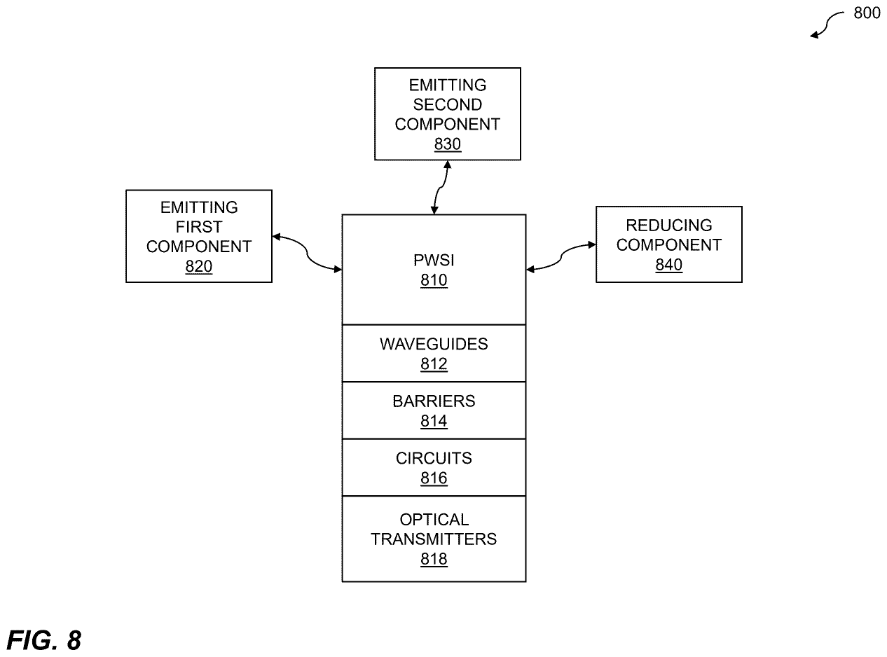

FIG. 8 is a system diagram for reduction of waveguide crosstalk with sub-wavelength structures. A plurality of waveguides is fabricated within a photonic wafer-scale interposer (PWSI). The plurality of waveguides includes a first waveguide and a second waveguide. Each waveguide can transmit a modulated light beam. The first waveguide and the second waveguide are within a physical spacing within the PWSI which enables evanescent coupling for at least a parallel distance. The evanescent coupling can cause crosstalk between the modulated beams in the waveguides. A sub-wavelength barrier is inserted between the first waveguide and the second waveguide. The sub-wavelength barrier is disposed between the first waveguide and the second waveguide for at least the parallel distance. A first modulated light beam is emitted through the first waveguide by a first optical transmitter, and a second modulated light beam is emitted through the second waveguide by a second optical transmitter. The sub-wavelength barrier reduces the evanescent coupling between the first modulated light beam and the second modulated light beam over the parallel distance.

Disclosed is a system for transmitting data comprising: a photonic wafer-scale interposer (PWSI); a plurality of waveguides, wherein the plurality of waveguides is fabricated within the PWSI, wherein the plurality of waveguides includes a first waveguide and a second waveguide, and wherein the first waveguide and the second waveguide are within a physical spacing, within the PWSI, which enables evanescent coupling for at least a parallel distance; a sub-wavelength barrier, wherein the sub-wavelength barrier is disposed between the first waveguide and the second waveguide for at least the parallel distance; a first optical transmitter, wherein the first optical transmitter is bonded to the PWSI; and second optical transmitter, wherein the second optical transmitter is bonded to the PWSI, wherein the system is configured to: emit, by the first optical transmitter, a first modulated light beam through the first waveguide; emit, by the second optical transmitter, a second modulated light beam through the second waveguide; and reduce, by the sub-wavelength barrier, the evanescent coupling between the first modulated light beam and the second modulated light beam over the parallel distance.

The system 800 includes a photonic wafer-scale interposer (PWSI) 810. The PWSI can comprise a wafer, where the wafer can include a silicon wafer, a glass wafer, and so on. The PWSI can include metal layers that can be used for interconnecting elements, where the elements can include electrical elements, photoelectric elements, and so on. The system 800 includes a plurality of waveguides 812, wherein the plurality of waveguides is fabricated within the PWSI, wherein the plurality of waveguides includes a first waveguide and a second waveguide, and wherein the first waveguide and the second waveguide are within a physical spacing, within the PWSI, which enables evanescent coupling for at least a parallel distance. The waveguides can be fabricated on or within the PWSI using a variety of techniques. In a usage example, the plurality of waveguides can be fabricated using a silicon-on-insulator technique such as described above. The waveguides can also be fabricated using one or more lithography techniques. In embodiments, the fabricating and the inserting are based on a nanoimprint lithography (NIL) process. The NIL process can include creating a stamp, compressing the stamp into resist applied to a PWSI, etching, resist removal, and so on. In embodiments, the NIL process comprises a full-wafer nanoimprint process.

The system 800 includes a sub-wavelength barrier 814, wherein the sub-wavelength barrier is disposed between the first waveguide and the second waveguide for at least the parallel distance. The inserting the sub-wavelength barrier can be fabricated using the NIL process. More than two waveguides and more than one sub-wavelength barrier can be included. In embodiments, the PWSI includes one or more additional waveguides and one or more additional sub-wavelength barriers. The sub-wavelength barrier comprises a width. In embodiments, the sub-wavelength barrier comprises a width less than the wavelength of light emitted by the first VCSEL and the wavelength of light emitted by the second VCSEL. The barrier is inserted to address crosstalk between waveguides. In embodiments, the sub-wavelength barrier reduces the evanescent coupling between the first modulated light beam and the second modulated light beam over the parallel distance. In a usage example, the sub-wavelength barrier eliminates the evanescent coupling between the first modulated light beam and the second modulated light beam over the parallel distance.

The system 800 includes a plurality of circuits 816. The plurality of circuits can include chips, cores, ASICs, SOIs, chiplets within a plurality of chiplets, and so on. In a usage example, the chiplets can include processor chiplets, memory chiplets, AI accelerator chiplets, switching chiplets, I/O chiplets, and so on. The circuits and chiplets can include cores, cores within circuits, cores on or within wafers, and the like. The system 800 includes optical transmitters 818. In embodiments, the system 800 includes a first optical transmitter, wherein the first optical transmitter is bonded to the PWSI. The first optical transmitter includes a surface-emitting light source that can emit a directly modulated light source. The system 800 includes a second optical transmitter, wherein the second optical transmitter is bonded to the PWSI. The second optical transmitter can also include a surface-emitting light source that can emit a directly modulated light source. A variety of surface-emitting light sources can be used. In some embodiments, the first optical transmitter comprises a first optical modulator, and the second optical transmitter comprises a second optical modulator. In certain embodiments, the first optical modulator includes a first ring resonator, and the second optical modulator includes a second ring resonator. Other surface-emitting light sources can be used, such as laser diodes. In embodiments, the first directly modulated light source comprises a first vertical-cavity surface-emitting laser (VCSEL), and the second directly modulated light source comprises a second VCSEL.

The system 800 includes an emitting first component 820. The emitting first component is configured to emit, by the first optical transmitter, a first modulated light beam through the first waveguide. The first optical transmitter can be a first ring resonator, a first VCSEL, and so on. As described above and throughout, a first VCSEL can be modulated to emit a first light beam which can be a first degree of freedom modulated beam (DFMB). The first DFMB can include an intensity of light, a polarization of light, a light mode, a light wavelength, and so on. The first DFMB can be coupled optically to a first waveguide within the PWSI. The first DFMB can be coupled optically to other optical media such as a fiberoptic cable, a multicore fiber, etc. The coupling optically can be accomplished using an optical coupler. The optical coupler can comprise a grating coupler. The grating coupler can include a periodic grating that can transfer the first DFMB with low loss into the first waveguide or other optical medium. The optical coupler can comprise a mirror. In a usage example, the mirror can include a nano-imprint lithography mirror. The first DFMB that was emitted by the first VCSEL can be angled. The angling can be based on a micro-optical element (MOE). The angling the first DFMB can be used to complement an angle associated with the coupling the first DFMB to the waveguide.

The system 800 includes an emitting second component 830. The emitting second component is configured to emit, by the second optical transmitter, a second modulated light beam through the second waveguide. Similar to the first emitting component, the second optical transmitter can be a second ring resonator, a second VCSEL, and so on. The first VCSEL and the second VCSEL can be co-located on the same chip, array, etc., or can be located on different chips, arrays, etc. The second VCSEL can be modulated to emit a second light beam which can be a second degree of freedom modulated beam (DFMB). The second DFMB can include an intensity of light, a polarization of light, a light mode, a light wavelength, and so on. The second DFMB can be coupled optically to a second waveguide within the PWSI. The first waveguide and the second waveguide can run in parallel for a distance. The first waveguide and the second waveguide can be spaced such that evanescent coupling is possible between the waveguides. The second DFMB can be coupled optically to other optical media such as a fiberoptic cable, a multicore fiber, etc. The coupling optically can be accomplished using an optical coupler. The optical coupler can comprise a grating coupler. The grating coupler can include a periodic grating that can transfer the second DFMB with low loss into the second waveguide or other optical medium. The optical coupler can comprise a mirror. In a usage example, the mirror can include a nano-imprint lithography mirror. The second DFMB that was emitted by the second VCSEL can be angled. The angling can be based on a micro-optical element (MOE). The angling the second DFMB can be used to complement an angle associated with the coupling the second DFMB to the waveguide.

The system 800 includes a reducing component 840. The reducing component is configured to reduce the evanescent coupling between the first modulated light beam and the second modulated light beam over the parallel distance. The reducing can be accomplished by the sub-wavelength barrier. Discussed previously, the sub-wavelength barrier comprises a width less than the wavelength of light emitted by the first VCSEL and the wavelength of light emitted by the second VCSEL The reducing component can reduce or eliminate the evanescent coupling between modulated light beams traveling in waveguides that are physically spaced to enable evanescent coupling for at least a parallel distance. The reduction of evanescent coupling can transfer data between a first circuit and a second circuit with minimally spaced waveguides. Embodiments include receiving, by the second circuit, the data that was sent, wherein the receiving is based on decoding the first modulated light beam.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagram and flow diagram illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions—generally referred to herein as a “circuit,” “module,” or “system”—may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for transmitting data comprising:
fabricating a plurality of waveguides within a photonic wafer-scale interposer (PWSI), wherein the plurality of waveguides includes a first waveguide and a second waveguide, and wherein the first waveguide and the second waveguide are within a physical spacing within the PWSI which enables evanescent coupling for at least a parallel distance;
inserting, between the first waveguide and the second waveguide, a sub-wavelength barrier, wherein the sub-wavelength barrier is disposed between the first waveguide and the second waveguide for at least the parallel distance; and
emitting a first modulated light beam through the first waveguide by a first optical transmitter, and a second modulated light beam through the second waveguide by a second optical transmitter, wherein the sub-wavelength barrier reduces the evanescent coupling between the first modulated light beam and the second modulated light beam over the parallel distance.

2. The method of claim 1 wherein the first waveguide and the second waveguide comprise co-propagating waveguides.

3. The method of claim 2 wherein the PWSI includes one or more additional waveguides and one or more additional sub-wavelength barriers.

4. The method of claim 1 wherein the first optical transmitter comprises a first optical modulator, and the second optical transmitter comprises a second optical modulator.

5. The method of claim 4 wherein the first optical modulator includes a first ring resonator, and the second optical modulator includes a second ring resonator.

6. The method of claim 1 wherein the first optical transmitter comprises a first directly modulated light source and the second optical transmitter comprises a second directly modulated light source.

7. The method of claim 6 wherein the first directly modulated light source comprises a first vertical-cavity surface-emitting laser (VCSEL), and the second directly modulated light source comprises a second VCSEL.

8. The method of claim 7 wherein a mode of light emitted by the first VCSEL is different than a mode of light emitted by the second VCSEL.

9. The method of claim 7 wherein a polarization of light emitted by the first VCSEL is different than a polarization of light emitted by the second VCSEL.

10. The method of claim 7 wherein a wavelength of light emitted by the first VCSEL is different than a wavelength of light emitted by the second VCSEL.

11. The method of claim 10 wherein the sub-wavelength barrier comprises a width less than the wavelength of light emitted by the first VCSEL and the wavelength of light emitted by the second VCSEL.

12. The method of claim 7 wherein the first VCSEL and the second VCSEL are bonded to the PWSI.

13. The method of claim 12 further comprising sending data, by a first circuit within a plurality of circuits bonded to the PWSI, to a second circuit within the plurality of circuits bonded to the PWSI, wherein the sending is based on the first modulated light beam.

14. The method of claim 13 wherein the emitting the first modulated light beam is based on modulating a degree of freedom of the first VCSEL.

15. The method of claim 14 further comprising receiving, by the second circuit, the data that was transmitted, wherein the receiving is based on decoding the first modulated light beam.

16. The method of claim 15 further comprising transferring other data, by a third circuit within the plurality of circuits bonded to the PWSI, to a fourth circuit within the plurality of circuits bonded to the PWSI, wherein the transferring is based on the second modulated light beam.

17. The method of claim 16 wherein the emitting the second modulated light beam is based on modulating a degree of freedom of the second VCSEL.

18. The method of claim 17 further comprising obtaining, by the fourth circuit, the other data that was transferred, wherein the obtaining is based on decoding the second modulated light beam.

19. The method of claim 1 wherein the fabricating and the inserting are based on a nanoimprint lithography (NIL) process.

20. The method of claim 19 wherein the first waveguide comprises a first distance and the second waveguide comprises a second distance, wherein the first distance and the second distance are greater than an exposure, on the PWSI, of a single photomask reticle.

21. The method of claim 19 wherein the NIL process comprises a full-wafer nanoimprint process.

22. The method of claim 1 wherein the sub-wavelength barrier comprises a silicon nitride barrier.

23. An apparatus for transmitting data comprising:
a photonic wafer-scale interposer (PWSI);
a plurality of waveguides, wherein the plurality of waveguides is fabricated within the PWSI, wherein the plurality of waveguides includes a first waveguide and a second waveguide, and wherein the first waveguide and the second waveguide are within a physical spacing, within the PWSI, which enables evanescent coupling for at least a parallel distance;
a sub-wavelength barrier, wherein the sub-wavelength barrier is disposed between the first waveguide and the second waveguide for at least the parallel distance;
a first optical transmitter, wherein the first optical transmitter is bonded to the PWSI and wherein the first optical transmitter emits a first modulated light beam through the first waveguide; and
a second optical transmitter, wherein the second optical transmitter is bonded to the PWSI and wherein the second optical transmitter emits a second modulated light beam through the second waveguide, wherein the sub-wavelength barrier reduces the evanescent coupling between the first modulated light beam and the second modulated light beam over the parallel distance.

24. The apparatus of claim 23 wherein the first optical transmitter comprises a first vertical-cavity surface-emitting laser (VCSEL), and wherein the second optical transmitter comprises a second VCSEL.

25. A system for transmitting data comprising:
a photonic wafer-scale interposer (PWSI);
a plurality of waveguides, wherein the plurality of waveguides is fabricated within the PWSI, wherein the plurality of waveguides includes a first waveguide and a second waveguide, and wherein the first waveguide and the second waveguide are within a physical spacing, within the PWSI, which enables evanescent coupling for at least a parallel distance;
a sub-wavelength barrier, wherein the sub-wavelength barrier is disposed between the first waveguide and the second waveguide for at least the parallel distance;
a first optical transmitter, wherein the first optical transmitter is bonded to the PWSI; and
a second optical transmitter, wherein the second optical transmitter is bonded to the PWSI;
wherein the system is configured to:
emit, by the first optical transmitter, a first modulated light beam through the first waveguide;
emit, by the second optical transmitter, a second modulated light beam through the second waveguide; and
reduce, by the sub-wavelength barrier, the evanescent coupling between the first modulated light beam and the second modulated light beam over the parallel distance.
